(19) United States
(12) Patent Application Publication
(10) Pub. No.: US 2025/0072204 A1
(43) Pub. Date: Feb. 27, 2025

(54) LIGHT-EMITTING DIODE, DISPLAY DEVICE, AND DEPOSITION APPARATUS

(71) Applicant: Samsung Display Co., Ltd., Yongin-si (KR)

(72) Inventors: Jinwoong Kim, Yongin-si (KR); Jungmin Moon, Yongin-si (KR); Youngtak Lee, Yongin-si (KR); Hyowon Choi, Yongin-si (KR)

(21) Appl. No.: 18/736,316

(22) Filed: Jun. 6, 2024

(30) Foreign Application Priority Data
Aug. 25, 2023 (KR) 10-2023-0112288

(51) Int. Cl. H10K 50/16; H10K 71/13; H10K 101/40; H10K 102/00

(52) U.S. Cl. CPC H10K 50/166; H10K 71/13; H10K 2101/40; H10K 2102/351

(57) ABSTRACT

A light-emitting diode includes a pixel electrode, a first functional layer on the pixel electrode, an emission layer on the first functional layer, a second functional layer on the emission layer, and an opposite electrode on the second functional layer, wherein the second functional layer includes an auxiliary electron transport layer on the emission layer and including a first deposition material, a mixed layer on the auxiliary electron transport layer and including the first deposition material, a second deposition material, and a third deposition material, and an electron transport layer on the mixed layer and including the second deposition material and the third deposition material.

### CROSS-REFERENCE TO RELATED APPLICATION

The present application claims priority to and the benefit of Korean Patent Application No. 10-2023-0112288, filed on Aug. 25, 2023, in the Korean Intellectual Property Office, the entire content of which is hereby incorporated by reference.

### BACKGROUND

### 1. Field

One or more embodiments of the present disclosure relate to a light-emitting diode, a display device including the light-emitting diode, and a deposition apparatus for forming the light-emitting diode. For example, one or more embodiments relate to a light-emitting diode including an electron transport layer, an auxiliary electron transport layer, and a mixed layer, a display device including the light-emitting diode, and a deposition apparatus for forming the light-emitting diode.

### 2. Description of the Related Art

Generally, a display device may include a light-emitting diode including a pixel electrode, an emission layer, and an opposite (e.g., counter) electrode. The light-emitting diode receives holes and electrons injected from a pixel electrode and the opposite electrode, respectively, to form excitons, and emits light as the excitons transition (e.g., relax) to the ground state. A deposition apparatus may be utilized to form an organic thin film, a metal thin film, etc. on a substrate of a display device. The deposition apparatus may include a deposition source including a deposition material and a spray port for spraying the deposition material. When the deposition source is heated to a set or predetermined temperature, the deposition material in the deposition source is vaporized, and the vaporized deposition material is sprayed through the spray port. If (e.g., when) the deposition material sprayed from the spray port is formed or deposited on the substrate, a thin film may be formed.

The above information disclosed in this Background section is provided for enhancement of understanding of the background of the present disclosure, and, therefore, it may contain information that does not constitute related (or prior) art.

### SUMMARY

Additional aspects will be set forth in part in the description which follows and, in part, will be apparent from the description, or may be learned by practice of the presented embodiments of the disclosure.

According to one or more embodiments of the present disclosure, a light-emitting diode includes a pixel electrode, a first functional layer on the pixel electrode, an emission layer on the first functional layer, a second functional layer on the emission layer, and an opposite (e.g., counter) electrode on the second functional layer, wherein the second functional layer includes an auxiliary electron transport layer on the emission layer and including a first deposition material, a mixed layer on the auxiliary electron transport layer and including the first deposition material, a second deposition material, and a third deposition material, and an electron transport layer on the mixed layer and including the second deposition material and the third deposition material.

In one or more embodiments, a lowest unoccupied molecular orbit (LUMO) energy level of the mixed layer may be lower than a LUMO energy level of the auxiliary electron transport layer and higher than a LUMO energy level of the electron transport layer.

In one or more embodiments, the LUMO energy level of the auxiliary electron transport layer may be lower than the LUMO energy level of the emission layer.

In one or more embodiments, a highest occupied molecular orbit (HOMO) energy level of the mixed layer may be lower than a HOMO energy level of the emission layer and a HOMO energy level of the electron transport layer.

In one or more embodiments, a thickness of the mixed layer may be less than a thickness of the electron transport layer.

In one or more embodiments, a thickness of the mixed layer may be about 20 angstrom (Å) to about 70 Å.

In one or more embodiments, a thickness of the mixed layer may be equal to or greater than a thickness of the auxiliary electron transport layer.

According to one or more embodiments of the present disclosure, a display device includes a substrate, a thin film transistor on the substrate, a pixel electrode electrically connected to the thin film transistor, a first functional layer on the pixel electrode; an emission layer on the first functional layer, a second functional layer on the emission layer, and an opposite electrode on the second functional layer, wherein the second functional layer includes an auxiliary electron transport layer on the emission layer and including a first deposition material, a mixed layer on the auxiliary electron transport layer and including the first deposition material, a second deposition material, and a third deposition material, and an electron transport layer on the mixed layer and including the second deposition material and the third deposition material.

In one or more embodiments, a LUMO energy level of the mixed layer may be lower than a LUMO energy level of the auxiliary electron transport layer and higher than a LUMO energy level of the electron transport layer.

In one or more embodiments, the LUMO energy level of the auxiliary electron transport layer may be lower than the LUMO energy level of the emission layer.

In one or more embodiments, a HOMO energy level of the mixed layer may be lower than a HOMO energy level of the emission layer and a HOMO energy level of the electron transport layer.

In one or more embodiments, a thickness of the mixed layer may be less than a thickness of the electron transport layer.

In one or more embodiments, the thickness of the mixed layer may be about 20 Å to about 70 Å.

According to one or more embodiments of the present disclosure, a deposition apparatus for forming a functional layer including an electron transport layer on a deposition substrate, includes a first deposition source, a second deposition source, and a third deposition source arranged with each other in a first direction, a first spray port configured to spray a first deposition material from the first deposition source to a first region of the deposition substrate, a second spray port configured to spray a second deposition material from the second deposition source to a second region of the deposition substrate, a third spray port configured to spray a third deposition material from the third deposition source to a third region of the deposition substrate, a first angle-limiting plate located outside the first spray port, a second angle-limiting plate between the first spray port and the second spray port, a third angle-limiting plate between the second spray port and the third spray port, and a fourth angle-limiting plate located outside the third spray port, wherein a portion of the first region overlaps with the second region and the third region.

In one or more embodiments, the second region may entirely overlap the third region.

In one or more embodiments, the first spray port may be limited (e.g., controlled) by the first angle-limiting plate to spray the first deposition material at a first incident angle to the deposition substrate, the first spray port may be limited by the second angle-limiting plate to spray the first deposition material at a second incident angle to the deposition substrate, and the first incident angle may be greater than the second incident angle.

In one or more embodiments, the second spray port is limited by the second angle-limiting plate to spray the second deposition material at a third incident angle to the deposition substrate and the second incident angle may be less than the third incident angle.

In one or more embodiments, the second incident angle may be about 55° to about 65.

In one or more embodiments, the third incident angle may be about 70° to about 80°.

In one or more embodiments, the second spray port is limited by the third angle-limiting plate to spray the second deposition material at a fourth incident angle to the deposition substrate, the third spray port is limited by the third angle-limiting plate to spray the third deposition material at a fifth incident angle to the deposition substrate, the fourth incident angle may be smaller than the third incident angle, the fourth incident angle may be smaller than the fifth incident angle, and the fifth incident angle may be smaller than the third incident angle.

### BRIEF DESCRIPTION OF THE DRAWINGS

The above and other aspects, features, and/or principles of certain embodiments of the present disclosure will be more apparent from the following description taken in conjunction with the accompanying drawings, in which:

FIG. 1 is a schematic cross-sectional view illustrating a deposition apparatus for depositing an auxiliary electron transport layer, a mixed layer, and an electron transport layer, according to one or more embodiments of the present disclosure;

FIG. 2 is a schematic cross-sectional view illustrating an auxiliary electron transport layer, a mixed layer, and an electron transport layer formed or deposited on the emission layer by the deposition apparatus of FIG. 1, according to one or more embodiments of the present disclosure;

FIG. 3 is a diagram illustrating band energies of an emission layer, an auxiliary electron transport layer, a mixed layer, and an electron transport layer, according to one or more embodiments of the present disclosure;

FIG. 4 is a graph showing the ratio of first to third deposition materials according to the thickness of a film formed or deposited by a deposition apparatus, according to one or more embodiments of the present disclosure;

FIG. 5 is a table showing driving voltage and luminance, according to comparative examples and embodiments of the present disclosure;

FIG. 6 is a graph showing current density versus voltage of the comparative examples and the embodiments of FIG. 5; and

FIG. 7 is a schematic cross-sectional view illustrating a display device including a light-emitting diode formed by a deposition apparatus, according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Reference will now be made in more detail to embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, the embodiments are merely described below, by referring to the drawings, to explain aspects of the present description. The embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As the disclosure allows for various changes and numerous embodiments, particular embodiments will be illustrated in the drawings and described in more detail in the written description. The effects and features of the disclosure, and ways to achieve them will become apparent by referring to embodiments that will be described later in more detail with reference to the drawings. However, the disclosure is not limited to the following embodiments but may be embodied in various forms.

Hereinafter, embodiments of the disclosure will be described in more detail with reference to the accompanying drawings, and in the description with reference to the drawings, like reference numerals refer to like elements and redundant descriptions thereof will not be provided.

It will be understood that, although the terms “first,” “second,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “below,” “lower,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

As used herein, the singular forms “a,” “an” and “the” are intended to include the plural forms as well, unless the context clearly indicates otherwise.

It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

It will be understood that when an element, such as an area, region, or layer, is referred to as being “on,” “connected to,” or “above” another element, it can be directly on, connected to, or coupled to the other element or one or more intervening elements may be present. For example, herein, when elements (e.g., areas, regions or layers) are described as being electrically connected, this indicates a case where elements are directly electrically connected and/or a case where elements are indirectly electrically connected with other elements therebetween. In addition, it will also be understood that when an element is referred to as being “between” two elements, it can be the only element between the two elements, or one or more intervening elements may also be present.

Herein, “A and/or B” may indicate only A, only B, or both A and B. Also, “at least one of A and B” may indicate only A, only B, or both A and B.

Herein, an x-axis, a y-axis, and a z-axis are not limited to three axes on a rectangular coordinate system, but may be construed as including these axes. For example, an-x axis, a y-axis, and a z-axis may be at right angles or may also indicate different directions from one another, which are not at right angles.

In the drawings, the sizes of elements may be exaggerated or reduced for convenience of explanation. For example, because sizes and thicknesses of elements in the drawings are illustrated (e.g., arbitrarily illustrated) for convenience of explanation, the following embodiments are not limited thereto.

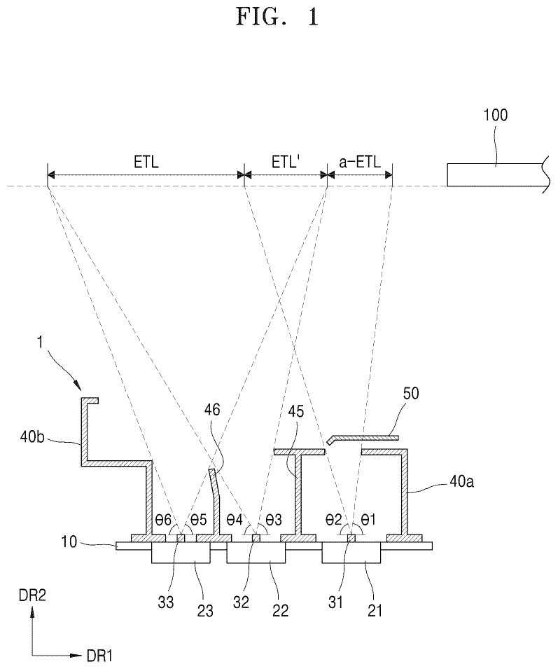

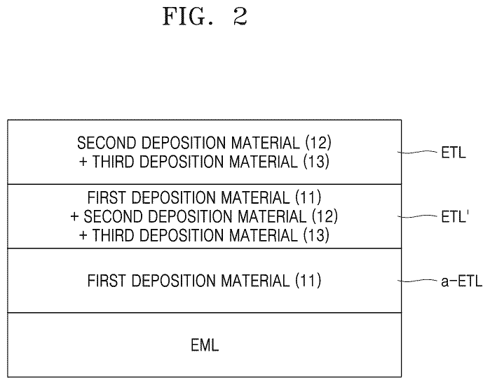

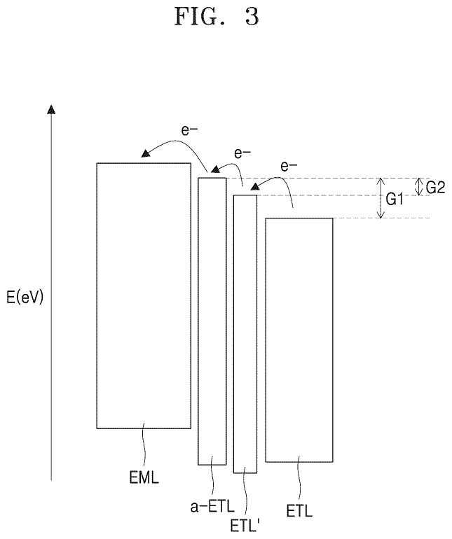

FIG. 1 is a schematic cross-sectional view illustrating a deposition apparatus 1 for depositing an auxiliary electron transport layer a-ETL, a mixed layer ETL′, and an electron transport layer ETL, according to one or more embodiments of the present disclosure. FIG. 2 is a schematic cross-sectional view illustrating the auxiliary electron transport layer a-ETL, a mixed layer ETL′, and an electron transport layer ETL formed or deposited on the emission layer EML by the deposition apparatus 1 of FIG. 1, according to one or more embodiments of the present disclosure. FIG. 3 is a diagram showing the band energies of the emission layer EML, the auxiliary electron transport layer a-ETL, the mixed layer ETL′, and the electron transport layer ETL, according to one or more embodiments of the present disclosure.

Referring to FIGS. 1 and 2, the deposition apparatus 1 may include a first deposition source 21, a second deposition source 22, and a third deposition source 23. The deposition apparatus 1 may include a first angle-limiting plate 40a, a second angle-limiting plate 45, a third angle-limiting plate 46, and a fourth angle-limiting plate 40b.

The first deposition source 21, the second deposition source 22, and the third deposition source 23 may be arranged with each other along a first direction DR1. The second deposition source 22 may be located between the first deposition source 21 and the third deposition source 23. In one or more embodiments, the first to third deposition sources 21, 22, and 23 may be located at (e.g., in) a single base 10.

The deposition apparatus 1 may reciprocate in the first horizontal direction (e.g., DR1 direction) and a second horizontal direction (e.g., −DR1 direction) opposite to the first horizontal direction (e.g., DR1 direction).

The first to third deposition sources 21, 22, and 23 may spray deposition materials. The first deposition source 21, the second deposition source 22, and the third deposition source 23 may respectively spray a first deposition material 11, a second deposition material 12, and a third deposition material 13. As the first to third deposition sources 21, 22, and 23 vaporize or sublimate the first to third deposition materials 11, 12, and 13 stored therein, respectively, the first to third deposition sources 21, 22, and 23 may respectively spray the first to third deposition materials 11, 12, and 13 in a direction in which a deposition substrate 100 is located (e.g., in DR2direction). In one or more embodiments, the first to third deposition sources 21, 22, and 23 include a crucible in which a deposition material is filled, and a heater for heating the crucible to vaporize or sublimate the deposition material filled inside the crucible.

The deposition apparatus 1 may further include a first spray port 31 formed or disposed on the first deposition source 21, a second spray port 32 formed or disposed on the second deposition source 22, and a third spray port 33 formed or disposed on the third deposition source 23. The first spray port 31 may spray the first deposition material 11 vaporized or sublimated in the first deposition source 21, in a direction in which the deposition substrate 100 is located (e.g., DR2 direction). The second spray port 32 may spray the second deposition material 12 vaporized or sublimated in the second deposition source 22, in a direction in which the deposition substrate 100 is located (e.g., DR2 direction). The third spray port 33 may spray the third deposition material 13 vaporized or sublimated in the third deposition source 23, in a direction in which the deposition substrate 100 is located (e.g., DR2 direction).

The deposition apparatus 1 may include first to fourth angle-limiting plates 40a, 45, 46, and 40b to limit the incident angle at which the first to third deposition materials 11, 12, and 13 are incident on the deposition substrate 100.

The first angle-limiting plate 40a may be located outside (e.g., adjacent to the outer side of) the first spray port 31. The fourth angle-limiting plate 40b may be located outside (e.g., adjacent to the outer side of) the third spray port 33. Each of the second angle-limiting plate 45 and the third angle-limiting plate 46 may be located between the first angle-limiting plate 40a and the fourth angle-limiting plate 40b. The second angle-limiting plate 45 may be located between the first spray port 31 and the second spray port 32. The third angle-limiting plate 46 may be located between the second spray port 32 and the third spray port 33.

In one or more embodiments of the present disclosure, an incident angle of the first deposition material 11 sprayed from the first spray port 31 limited by the first angle-limiting plate 40a, with respect to the deposition substrate 100, may be defined as a first incident angle θ1 (e.g., the first spray port 31 may be limited by the first angle-limiting plate 40a such that the first deposition material 11 is sprayed at the first incident angle θ1 to the deposition substrate 100). An incident angle of the first deposition material 11 sprayed from the first spray port 31 limited by the second angle-limiting plate 45, with respect to the deposition substrate 100, may be defined as a second incident angle θ2 (e.g., the first spray port 31 may be limited by the second angle-limiting plate 45 such that the first deposition material 11 is sprayed at the second incident angle θ2 to the deposition substrate 100). An incident angle of the second deposition material 12 sprayed from the second spray port 32 limited by the second angle-limiting plate 45, with respect to the deposition substrate 100, may be defined as a third incident angle θ3 (e.g., the second spray port 32 may be limited by the second angle-limiting plate 45 such that the second deposition material 12 is sprayed at the third incident angle θ3 to the deposition substrate 100). An incident angle of the second deposition material 12 sprayed from the second spray port 32 limited by the third angle-limiting plate 46, with respect to the deposition substrate 100, may be defined as a fourth incident angle θ4 (e.g., the second spray port 32 may be limited by the third angle-limiting plate 46 such that the second deposition material 12 is sprayed at the fourth incident angle θ4 to the deposition substrate 100). An incident angle of the third deposition material 13 sprayed from the third spray port 33 limited by the third angle-limiting plate 46, with respect to the deposition substrate 100, may be defined as a fifth incident angle θ5 (e.g., the third spray port 33 may be limited by the third angle-limiting plate 46 such that the third deposition material 13 is sprayed at the fifth incident angle θ5 to the deposition substrate 100). An incident angle of the third deposition material 13 sprayed from the third spray port 33 limited by the fourth angle-limiting plate 40b, with respect to the deposition substrate 100, may be defined as a sixth incident angle θ6 (e.g., the third spray port 33 may be limited by fourth angle-limiting plate 40b such that the third deposition material 13 is sprayed at the sixth incident angle θ6 to the deposition substrate 100).

The first to fourth angle-limiting plates 40a, 45, 46, and 40b may limit the incident angles of the first to third deposition materials 11, 12, and 13 such that a portion of a first region where the first deposition material 11 is formed or deposited overlaps a second region in which the second deposition material 12 is formed or deposited and a third region in which the third deposition material 13 is formed or deposited. For example, the first to fourth angle-limiting plates 40a, 45, 46, and 40b may limit the incident angles of the first to third deposition material 11, 12, and 13 such that the second deposition material 12 and the third deposition material 12 are formed or deposited together with the first deposition material 11 in the portion of the first region where the first deposition material 11 is formed or deposited, and only the first deposition material 11 is formed or deposited in the remaining region of the first region. The first to fourth angle-limiting plates 40a, 45, 46, and 40b may limit the incident angles of the second and third deposition materials 12 and 13 such that the entire second region where the second deposition material 12 is formed or deposited overlaps the third region where the third deposition material 13 is formed or deposited. Accordingly, the deposition apparatus 1 may form the auxiliary electron transport layer a-ETL including the first deposition material 11, the mixed layer ETL′ including the first deposition material 11, the second deposition material 12, and the third deposition material 13, and the electron transport layer ETL including the second deposition material 12 and the third deposition material 13.

The first incident angle θ1 may be greater than the second incident angle θ2. For example, the first incident angle θ1 may be about 75° to about 85°. For example, the second incident angle θ2 may be about 55° to about 65°. The second incident angle θ2 may be smaller than the third incident angle θ3. The third incident angle θ3 may be smaller than the first incident angle θ1. For example, the third incident angle θ3 may be about 70° to about 80°. The fourth incident angle θ4 may be smaller than the second incident angle θ2. The fourth incident angle θ4 may be smaller than the third incident angle θ3. For example, the fourth incident angle θ4 may be about 35° to about 45°. The fifth incident angle θ5 may be smaller than the third incident angle θ3. The fifth incident angle θ5 may be greater than the fourth incident angle θ4. For example, the fifth incident angle θ5 may be about 45° to about 55°. The sixth incident angle θ6 may be greater than the fourth incident angle θ4. The sixth incident angle θ6 may be greater than the fifth incident angle θ5. For example, the sixth incident angle θ6 may be about 50° to about 60°.

In one or more embodiments of the present disclosure, by the second and third angle-limiting plates 45 and 46, the second incident angle θ2 is limited to be smaller than the third incident angle θ3, and the fifth incident angle θ5 is limited to be smaller than the third incident angle θ3, and thus, the first deposition material 11, the second deposition material 12, and the third deposition material 13 may be formed or deposited together to form the mixed layer ETL′. For example, as the second incident angle θ2 is limited to be about 55° to about 65°, the third incident angle θ3 is limited to be about 70° to about 80°, and the fifth incident angle θ5 is limited to be about 45° to about 55°, and thus, the first deposition material 11, the second deposition material 12, and the third deposition material 13 may be formed or deposited together to form the mixed layer ETL′.

In one or more embodiments of the present disclosure, by the second to fourth angle-limiting plates 45, 46, 40b, the fifth incident angle θ5 is limited to be smaller than the third incident angle θ3, and the fourth incident angle θ4 is limited to be smaller than the sixth angle-limiting plate θ6, and thus, the second deposition material 12 and the third deposition material 13 may be formed or deposited together to form the electron transport layer ETL. For example, as the third incident angle θ3 is limited to be about 70° to about 80°, the fourth incident angle θ4 is limited to be about 35° to about 45°, and the fifth incident angle θ5 is limited to be about 45° to about 55°, and the sixth incident angle θ6 is limited to be about 50° to about 60°, the second deposition material 12 and the third deposition material 13 may be formed or deposited together to form the electron transport layer ETL.

The deposition apparatus 1 may further include a slide shutter 50. The slide shutter 50 is located above the first spray port 31 and may control deposition of the first deposition material 11 by reciprocating in the first horizontal direction (e.g., DR1 direction).

For example, when the deposition apparatus 1 has closed the slide shutter 50, the slide shutter 50 may move in the second horizontal direction (e.g., −DR1 direction) which is opposite to the first horizontal direction (e.g., DR1 direction) to block or reduce a spray path of the first spray port 31 and block or reduce deposition of the first deposition material 11. In one or more embodiments, when the deposition apparatus 1 has opened the slide shutter 50, the slide shutter 50 may move in the first horizontal direction (e.g., DR1 direction) to open the spray path of the first spray port 31.

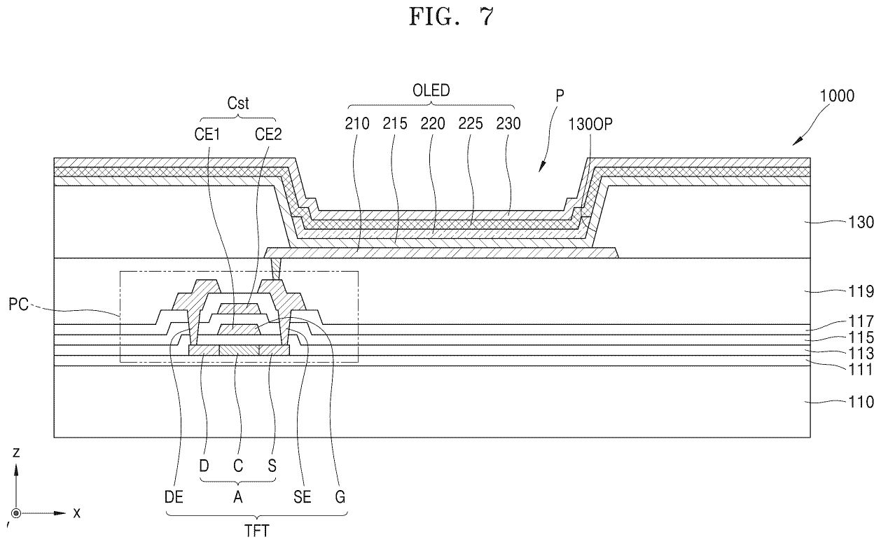

Referring to FIG. 2, by the deposition apparatus 1 described with reference to FIG. 1, the auxiliary electron transport layer a-ETL, the mixed layer ETL′, and the electron transport layer ETL may be stacked sequentially. A second functional layer 225 of an organic light-emitting diode OLED, which will be described in more detail with reference to FIG. 7, has a multilayer structure including the auxiliary electron transport layer a-ETL, the mixed layer ETL′, and the electron transport layer ETL.

The first to third deposition sources 21, 22, and 23 may reciprocate in the first horizontal direction (e.g., DR1 direction) and deposit the first to third deposition materials 11, 12, and 13 on the deposition substrate 100 to form the auxiliary electron transport layer a-ETL, the mixed layer ETL′, and the electron transport layer ETL. While spraying the first to third deposition materials 11, 12, and 13 through the first to third spray ports 31, 32, and 33, respectively, the first to third spray ports 31, 32, and 33 may reciprocate in the first horizontal direction (e.g., DR1 direction) together with the first to fourth angle-limiting plates 40a, 45, 46, and 40b. The first horizontal direction (e.g., DR1 direction) may be a direction from the second spray port 32 to the first spray port 31.

An emission layer EML may be formed or disposed on the deposition substrate 100 as illustrated in FIG. 2, and the auxiliary electron transport layer a-ETL, the mixed layer ETL′, and the electron transport layer ETL may be sequentially stacked on the emission layer EML.

The auxiliary electron transport layer a-ETL including the first deposition material 11 may be formed or disposed on the emission layer EML. The mixed layer ETL′ including the first to third deposition materials 11, 12, and 13 may be formed or disposed on the auxiliary electron transport layer a-ETL. The mixed layer ETL′ may be arranged between the auxiliary electron transport layer a-ETL and the electron transport layer ETL. The electron transport layer ETL including the second and third deposition materials 12 and 13 may be formed or disposed on the mixed layer ETL′. The electron transport layer ETL may be formed or disposed on the auxiliary electron transport layer a-ETL.

The thickness of the auxiliary electron transport layer a-ETL may be less than the thickness of the electron transport layer ETL.

The thickness of the mixed layer ETL′ may be less than the thickness of the electron transport layer ETL. The thickness of the mixed layer ETL′ may be substantially the same as or greater than the thickness of the auxiliary electron transport layer a-ETL, but the present disclosure is not limited thereto. The thickness of the mixed layer ETL′ may be, for example, about 20 angstrom (Å) to about 70 Å. When the incident angle is limited by the angle-limiting plates of the deposition apparatus 1, as in one or more embodiments of the present disclosure, the thickness of the mixed layer ETL′ may be about 20 Å to about 70 Å. In one or more embodiments, the thickness of the mixed layer ETL′ may be, for example, about 40 Å to about 70 Å. If (e.g., when) the thickness of the mixed layer ETL′ is less than 20 Å, electron movement may be relatively difficult and the driving voltage may increase, and if (e.g., when) the thickness of the mixed layer is greater than 70 Å, the thickness of the electron transport layer ETL may become relatively small, deteriorating the characteristics of the electron transport layer ETL.

In one or more embodiments, the deposition apparatus 1 may move in the first horizontal direction (e.g., DR1 direction) with the slide shutter 50 open so that the first spray port 31 faces the deposition substrate 100 including the emission layer EML to thereby sequentially form the auxiliary electron transport layer a-ETL, the mixed layer ETL′, and a portion of the electron transport layer ETL, and with the slide shutter 50 closed, the deposition apparatus 1 may move in the second horizontal direction (e.g., −DR1 direction) to form the other portions of the electron transport layer ETL. The number of reciprocating movements of the deposition apparatus 1 may vary depending on the embodiment(s).

Referring to FIG. 3, the lowest unoccupied molecular orbitals (LUMO) energy level of each of the emission layer EML, the auxiliary electron transport layer a-ETL, the mixed layer ETL′, and the electron transport layer ETL are shown.

The LUMO energy level of the emission layer EML may be higher than the LUMO energy level of the electron transport layer ETL. The absolute value of the LUMO energy level of the emission layer EML may be smaller than the absolute value of the LUMO energy level of the electron transport layer ETL.

The LUMO energy level of the auxiliary electron transport layer a-ETL may be lower than the LUMO energy level of the emission layer EML and higher than the LUMO energy level of the electron transport layer ETL. The absolute value of the LUMO energy level of the auxiliary electron transport layer a-ETL may be greater than the absolute value of the LUMO energy level of the emission layer EML and may be smaller than the absolute value of the LUMO energy level of the electron transport layer ETL. The absolute value of the LUMO energy level of the auxiliary electron transport layer a-ETL may be, for example, about 1.75 or less. The absolute value of the LUMO energy level of the electron transport layer ETL may be, for example, about 2.0 or more. A gap G1 between the absolute value of the LUMO energy level of the auxiliary electron transport layer a-ETL and the absolute value of the energy level of the electron transport layer ETL may be, for example, about 0.25 eV to about 0.5 eV.

The LUMO energy level of the mixed layer ETL′ may be lower than the LUMO energy level of the auxiliary electron transport layer a-ETL and higher than the LUMO energy level of the electron transport layer ETL. The absolute value of the LUMO energy level of the mixed layer ETL′ may be greater than the absolute value of the LUMO energy level of the auxiliary electron transport layer a-ETL and may be smaller than the absolute value of the LUMO energy level of the electron transport layer ETL. A gap G2 between the absolute value of the LUMO energy level of the mixed layer ETL′ and the absolute value of the energy level of the electron transport layer ETL may be smaller than the gap G1 between the absolute value of the LUMO energy level of the auxiliary electron transport layer a-ETL and the absolute value of the energy level of the electron transport layer ETL.

The mixed layer ETL′ may be arranged between the auxiliary electron transport layer a-ETL and the electron transport layer ETL, and have a LUMO energy level value between the LUMO energy level of the auxiliary electron transport layer a- ETL and the LUMO energy level of the electron transport layer ETL, and thus, the mixed layer ETL′ may facilitate electron movement from the electron transport layer ETL to the auxiliary electron transport layer a-ETL. Accordingly, the movement of electrons from the electron transport layer ETL to the emission layer EML through the auxiliary electron transport layer a-ETL may be facilitated, and thus the driving voltage of the light-emitting diode may be reduced.

The auxiliary electron transport layer a-ETL may be referred to as a hole blocking layer. The Highest Occupied Molecular Orbital (HOMO) energy level of the auxiliary electron transport layer a-ETL is lower than the HOMO energy level of the emission layer EML and may be lower than the HOMO energy level of the electron transport layer ETL. The absolute value of the HOMO energy level of the auxiliary electron transport layer a-ETL may be greater than the absolute value of the HOMO energy level of the emission layer EML, and may be greater than or equal to the absolute value of the HOMO energy level of the electron transport layer ETL.

The HOMO energy level of the mixed layer ETL′ may be lower than the HOMO energy level of the auxiliary electron transport layer a-ETL. The absolute value of the HOMO energy level of the mixed layer ETL′ may be greater than the absolute value of the HOMO energy level of the auxiliary electron transport layer a-ETL. The HOMO energy level of the mixed layer ETL′ may be lower than the HOMO energy level of the electron transport layer ETL. The absolute value of the HOMO energy level of the mixed layer ETL′ may be greater than the absolute value of the HOMO energy level of the electron transport layer ETL. The HOMO energy level of the mixed layer ETL′ may be lower than the HOMO energy level of the emission layer EML. The absolute value of the HOMO energy level of the mixed layer ETL′ may be greater than the absolute value of the HOMO energy level of the emission layer EML.

Referring back to FIG. 2, the auxiliary electron transport layer a-ETL may include the first deposition material 11 so that the absolute value of the LUMO energy level of the auxiliary electron transport layer a-ETL is smaller than that of the electron transport layer ETL. The absolute value of the LUMO energy level of a layer formed or deposited utilizing the first deposition material 11 may be smaller than the absolute value of the LUMO energy level of a layer formed or deposited utilizing the second deposition material 12 and the third deposition material 13. The electron mobility of the layer in which the first deposition material 11 is formed or deposited may be greater than the electron mobility of the layer in which the second deposition material 12 and the third deposition material 13 are formed or deposited. For example, the electron mobility of the auxiliary electron transport layer a-ETL may be greater than that of the electron transport layer ETL. The first deposition material 11 may include, for example, a triazine-based compound, 2,9-dimethyl-4,7-diphenyl-1,10-phenanthroline (BCP) or 4,7-diphenyl-1,10-phenanthroline (Bphen), etc., but the present disclosure is not limited thereto.

The electron transport layer ETL may include the second deposition material 12 and the third deposition material 13 so that the absolute value of the LUMO energy level of the electron transport layer ETL is greater than that of the auxiliary electron transport layer a-ETL. The second deposition material 12 and the third deposition material 13 may include, for example, a triazine-based compound or an anthracene-based compound, but the present disclosure is not limited thereto. The first deposition material 11, the second deposition material 12, and the third deposition material 13 may include different materials from each other. For example, the first deposition material 11, the second deposition material 12, and the third deposition material 13 may each include triazine-based compounds having different substituents. The second deposition material 12 and the third deposition material 13 may include, for example, tris (8-hydroxyquinolinato) aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 1,3,5-Tri(1-phenyl-1H-benzo[d]imidazol-2-yl)phenyl (TPBi), 2,9-Dimethyl-4,7-diphenyl-1,10-phenanthroline (BCP), 4,7-Diphenyl-1,10-phenanthroline (Bphen), 3-(4-Biphenyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), bis(2-methyl-8-quinolinolato-N1,O8)-(1,1′-Biphenyl-4-olato)aluminum (BAlq), beryllium bis(benzoquinolin-10-olate (Bebq2), 9,10-di(naphthalene-2-yl)anthracene (ADN), and/or any suitable mixture thereof.

The mixed layer ETL′ may include a material included in the auxiliary electron transport layer a-ETL and a material included in the electron transport layer ETL. According to one or more embodiments, the second incident angle θ2 at which the first deposition material 11 is incident on the deposition substrate 100 is limited to be about 55° to about 65°, by the second angle-limiting plate 45, and the first deposition material 11 may be formed or deposited together with the second and third deposition materials 12 and 13 to form the mixed layer ETL′.

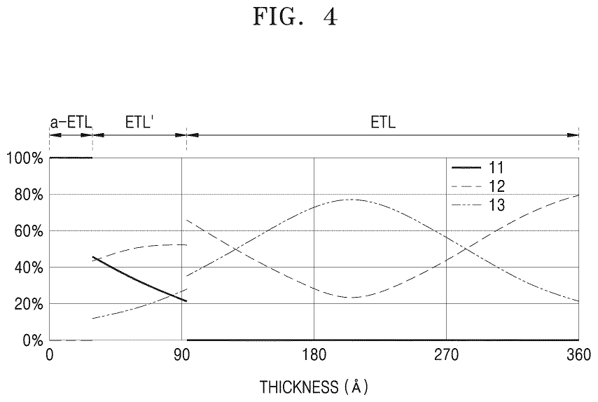

FIG. 4 is a graph showing the ratio of first to third deposition materials according to the thickness of a film formed or deposited by a deposition apparatus according to one or more embodiments of the present disclosure. In detail, FIG. 4 shows the ratio of a material according to a thickness of a layer formed or deposited by a deposition apparatus in which the first incident angle θ1 is limited to 78°, the second incident angle θ2 is limited to 60°, the third incident angle θ3 is limited to 72°, the fourth incident angle θ4 is limited to 38°, the fifth incident angle θ5 is limited to 50°, and the sixth incident angle θ6 is limited to 53°.

Referring to FIG. 4, the auxiliary electron transport layer a-ETL in which only the first deposition material 11 is deposited is formed in a lowermost layer of the deposited film. The auxiliary electron transport layer a-ETL has a thickness of about 30 Å. The mixed layer ETL′ in which the first to third deposition materials 11, 12, and 13 are deposited is formed on the auxiliary electron transport layer a-ETL. The mixed layer ETL′ has a thickness of about 64 Å. The electron transport layer ETL in which the second and third deposition materials 12 and 13 are deposited is formed on the mixed layer ETL′. The electron transport layer ETL has a thickness of approximately 261 Å.

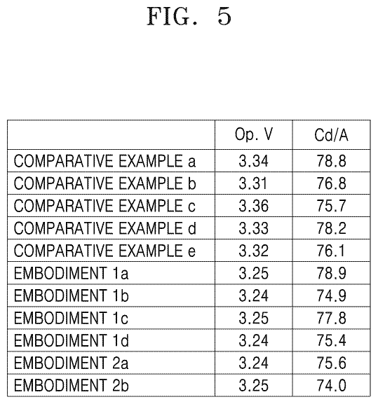

As described above, when the incident angle conditions of the first to third deposition materials 11, 12, and 13 are limited by the angle-limiting plates 40a, 45, 46, and 40b of the deposition apparatus 1 according to one or more embodiments, the mixed layer ETL′ may have a thickness within a range of 20 Å to 70 Å. The mixed layer ETL′ facilitates electron movement from the electron transport layer ETL to the auxiliary electron transport layer a-ETL, as described, for example, with reference to FIG. 3, and thus, a light-emitting diode formed utilizing the deposition apparatus 1 according to one or more embodiments may have improved electrical characteristics as the driving voltage is reduced, as described, for example, with reference to FIG. 5.

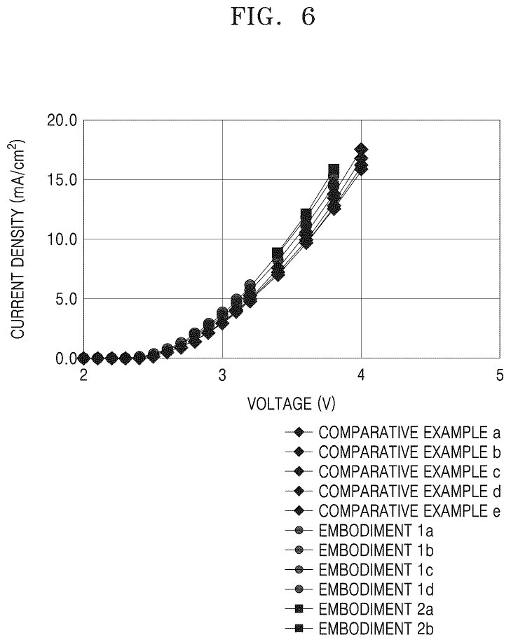

FIG. 5 is a table showing driving voltage (Op. V) and luminance (Cd/A), according to Comparative Examples and Embodiments. FIG. 6 is a graph showing current density versus voltage of the Comparative Examples and the Embodiments of FIG. 5.

In Comparative Examples (a) to (e), the driving voltage, luminance, and current density with respect to voltage were measured at a plurality of points of a light-emitting diode formed or deposited by a deposition apparatus making a round-trip movement, wherein in the deposition apparatus, the first incident angle θ1 is limited to 78°, the second incident angle θ2 is limited to 74°, the third incident angle θ3 is limited to 72°, the fourth incident angle θ4 is limited to 38°, the fifth incident angle θ5 is limited to 50°, and the sixth incident angle θ6 is limited to 53°.

In Embodiments 1a to 1d, the driving voltage, luminance, and current density with respect to voltage were measured at a plurality of points of a light-emitting diode formed or deposited by a deposition apparatus making a round-trip movement, wherein in the deposition apparatus, the first incident angle θ1 is limited to 78°, the second incident angle θ2 is limited to 60°, the third incident angle θ3 is limited to 72°, the fourth incident angle θ4 is limited to 38°, the fifth incident angle θ5 is limited to 50°, and the sixth incident angle θ6 is limited to 53°.

In Embodiments 2a and 2b, the driving voltage, luminance, and current density with respect to voltage were measured at a plurality of points of a light-emitting diode formed or deposited by a deposition apparatus making two round-trip movements, wherein in the deposition apparatus, the first incident angle θ1 is limited to 78°, the second incident angle θ2 is limited to 60°, the third incident angle θ3 is limited to 72°, the fourth incident angle θ4 is limited to 38°, the fifth incident angle θ5 is limited to 50°, and the sixth incident angle θ6 is limited to 53°.

Referring to FIG. 5, the Comparative Examples and Embodiments showed driving voltage values within a substantially similar luminance range, in a range of 74 Cd/A to 78.9 Cd/A. Comparative Examples (a) to (e) had driving voltage values in a range of 3.31 V to 3.36 V. Embodiments 1a to 1d had driving voltage values in a range of 3.24 V to 3.25 V. Embodiments 2a and 2b have driving voltage values in a range of 3.24 V to 3.25 V.

In Embodiments 1a to 2b, where the second incident angle θ2 is 65° or less, lower driving voltage values were exhibited compared to Comparative Examples (a) to (e), where the second incident angle θ2 is greater than 65°. Accordingly, as described with reference to FIG. 4, as the light-emitting diode formed by the deposition apparatus with the second incident angle θ2 limited to 65° or less includes the mixed layer ETL′, electron movement is facilitated and thus the driving voltage is reduced.

Referring to FIG. 6, values of current density (Current Density) at the same voltage in each of Embodiments 1a to 2b are greater than the values of Comparative Examples (a) to (d). For example, the slope in the current density graph with respect to each voltage of Embodiments 1a to 2b is greater than the slope of Comparative Examples (a) to (d). As described above, the electrical characteristics of the embodiments are improved, as the current density at the same voltage is increased compared to the Comparative Examples.

FIG. 7 is a schematic cross-sectional view illustrating a display device including a light-emitting diode formed by a deposition apparatus, according to one or more embodiments of the present disclosure.

Referring to FIG. 7, a display device 1000 may include a light-emitting diode that emits light. In FIG. 7, the light-emitting diode included in the display device 1000 is illustrated as an organic light-emitting diode OLED, but the present disclosure is not limited thereto. For example, the light-emitting diode may be an organic light-emitting diode, an inorganic light-emitting diode, or a quantum dot light-emitting diode. Hereinafter, for convenience of description, a case where the light-emitting diode is an organic light-emitting diode will be described. The display device 1000 includes a pixel P, and the pixel P may be to emit light having a certain color by utilizing the organic light-emitting diode OLED.

The organic light-emitting diode OLED may be electrically connected to a pixel circuit PC between the substrate 110 and the organic light-emitting diode OLED along a direction normal (e.g., perpendicular) to a substrate 110 (e.g., z-direction, e.g., in a plan view).

The substrate 110 may include glass material or polymer resin. In one or more embodiments, the substrate 110 may have an alternating stack structure of a base layer containing a polymer resin and a barrier layer containing an inorganic insulating material such as silicon oxide or silicon nitride. The polymer resin may include at least one of polyethersulfone, polyarylate, polyether imide, polyethylene naphthalate, polyethylene terephthalate, polyphenylene sulfide, polyimide, polycarbonate, cellulose triacetate, cellulose acetate propionate, or the like.

Before the pixel circuit PC is formed, a buffer layer 111 may be formed on the substrate 110 to prevent or reduce impurities from penetrating into the pixel circuit PC. The buffer layer 111 may include an inorganic insulating material such as silicon nitride, silicon oxynitride, and/or silicon oxide, and may include a single-layer or multi- layer structure including the inorganic insulating material.

The pixel circuit PC may include a thin film transistor TFT and a storage capacitor Cst. The thin film transistor TFT may include a semiconductor layer A, a gate electrode G, a source electrode SE, and a drain electrode DE.

The semiconductor layer A may be formed or disposed on the buffer layer 111. The semiconductor layer A may include polysilicon. In one or more embodiments, the semiconductor layer A may include amorphous silicon, an oxide semiconductor, an organic semiconductor, etc. In one or more embodiments, the semiconductor layer A may include a channel region C and a source region S and a drain region D arranged on opposite sides (e.g., both sides) of the channel region C, respectively.

The gate electrode G may overlap the channel region C of the semiconductor layer A. The gate electrode G may include a low-resistance metal material.

The first inorganic insulating layer 113 may be arranged between the semiconductor layer A and the gate electrode G. The first inorganic insulating layer 113 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO).

The second inorganic insulating layer 115 may cover the gate electrode G. Similar to the first inorganic insulating layer 113, the second inorganic insulating layer 115 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO).

The upper electrode CE2 of the storage capacitor Cst may be formed or disposed on the second inorganic insulating layer 115. In one or more embodiments, the upper electrode CE2 may overlap the gate electrode G. The gate electrode G and the upper electrode CE2 overlapping each other with the second inorganic insulating layer 115 therebetween may form the storage capacitor Cst. For example, the gate electrode G may function as a lower electrode CE1 of the storage capacitor Cst. As described above, the storage capacitor Cst and the thin film transistor TFT may overlap each other. In one or more embodiments, the storage capacitor Cst and the thin film transistor TFT may not overlap each other.

The third inorganic insulating layer 117 may cover the upper electrode CE2. The third inorganic insulating layer 117 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), and/or the like. The third inorganic insulating layer 117 may be a single layer or a multilayer including the inorganic insulating material described above.

The source electrode SE and the drain electrode DE may each be formed or disposed on the third inorganic insulating layer 117. At least one of the source electrode SE and/or the drain electrode DE may include a material having good or suitable conductivity. At least one of the source electrode SE or the drain electrode DE may include a conductive material including molybdenum (Mo), aluminum (Al), copper (Cu), titanium (Ti), and/or the like, and may be provided as a multi-layer or single layer including the materials described above. In one or more embodiments, at least one of the source electrode SE or the drain electrode DE may have a multilayer structure of Ti/Al/Ti.

The organic insulating layer 119 may be formed or disposed on the third inorganic insulating layer 117. The organic insulating layer 119 may be formed or disposed on the source electrode SE and the drain electrode DE. The organic insulating layer 119 may include an organic material. The organic insulating layer 119 may include an organic insulating material such as general-purpose polymers such as polymethylmethacrylate (PMMA) or polystyrene (PS), polymer derivatives with phenolic groups, acrylic polymers, imide polymers, aryl ether polymers, amide polymers, fluorine polymers, p-xylene-based polymers, vinyl alcohol-based polymers, and/or suitable blends thereof.

A light-emitting diode, for example, an organic light-emitting diode OLED, may be formed or disposed on the organic insulating layer 119. For example, the organic light-emitting diode OLED may be to emit red, green, or blue light, or may be to emit red, green, blue, or white light. The organic light-emitting diode OLED may include a pixel electrode 210, an emission layer 220, and an opposite electrode 230. The organic light-emitting diode OLED may further include a first functional layer 215 between the pixel electrode 210 and the emission layer 220 and a second functional layer 225 between the emission layer 220 and the opposite electrode 230.

The pixel electrode 210 may be formed or disposed on the organic insulating layer 119. The pixel electrode 210 may be electrically connected to the thin film transistor TFT. For example, the pixel electrode 210 may be connected to the thin film transistor TFT through a contact hole in the organic insulating layer 119. The pixel electrode 210 may include a conductive oxide such as indium tin oxide (ITO), indium zinc oxide (IZO), zinc oxide (ZnO), indium oxide (In₂O₃), indium gallium oxide (IGO) and/or aluminum zinc oxide (AZO). In one or more embodiments, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), and/or any suitable compound thereof. In one or more embodiments, the pixel electrode 210 may further include a layer including ITO, IZO, ZnO, or In₂O₃ above and/or below the above-described reflective layer.

A pixel defining layer 130 having an opening 130OP exposing a central portion of the pixel electrode 210 may be formed or disposed on the pixel electrode 210. The pixel defining layer 130 may include an organic insulating material and/or an inorganic insulating material. The opening 130OP of the pixel defining layer 130 may define a light-emitting area of light emitted from the organic light-emitting diode OLED.

The emission layer 220 may be arranged in the opening 130OP of the pixel defining layer 130. The emission layer 220 may include a polymer or low-molecular organic material that emits light of a certain color. The emission layer 220 may correspond to the emission layer EML described with reference to FIGS. 1 to 4.

The first functional layer 215 may be formed or disposed below the emission layer 220. The first functional layer 215 may be formed or disposed on the pixel electrode 210. The first functional layer may include, for example, a hole transport layer (HTL) or an HTL and a hole injection layer (HIL). The first functional layer 215 may be a common layer formed to entirely cover the substrate 110, similar to the opposite electrode 230, which will be described in more detail later.

The deposition substrate 100 described with reference to FIG. 1 may include a stacked structure including the substrate 110, the thin film transistor TFT on the substrate 110, the pixel electrode 210 electrically connected to the thin film transistor TFT, the first functional layer 215 on the pixel electrode 210, and the emission layer 220 on the first functional layer 215 of FIG. 7.

The second functional layer 225 may be formed or disposed on the emission layer 220. The second functional layer 225 may include the auxiliary electron transport layer a-ETL, the mixed layer ETL′, and the electron transport layer ETL as described, for example, with reference to FIGS. 1 to 4. As the organic light-emitting diode OLED according to one or more embodiments includes the second functional layer 225 including the auxiliary electron transport layer a-ETL, the mixed layer ETL′, and the electron transport layer ETL, electrical characteristics and display quality of the organic light-emitting diode OLED may be improved. In one or more embodiments, the second functional layer 225 may further include an electron injection layer (EIL). The second functional layer 225 may be a common layer formed to entirely cover the substrate 110, similar to the opposite electrode 230, which will be described in more detail later.

The opposite electrode 230 may be formed or disposed on the emission layer 220. The opposite electrode 230 may entirely cover the substrate 110. The opposite electrode 230 may include a conductive material having a low work function. For example, the opposite electrode 230 may include a (semi) transparent layer including Ag, Mg, Al, Pt, Pd, Au, Ni, Nd, Ir, Cr, Li, Ca, and/or any suitable alloy thereof. In one or more embodiments, the opposite electrode 230 may further include a layer such as ITO, IZO, ZnO and/or In₂O₃ on the (semi) transparent layer including the above-described material.

In one or more embodiments, an encapsulation layer may be formed or disposed on the organic light-emitting diode OLED. The encapsulation layer may include at least one inorganic encapsulation layer and at least one organic encapsulation layer covering the organic light-emitting diode OLED. In one or more embodiments, at least one inorganic encapsulation layer and at least one organic encapsulation layer may be alternately stacked. The inorganic encapsulation layer may include at least one inorganic material of (e.g., at least one inorganic material selected from among) aluminum oxide (Al₂O₃), titanium oxide (TiO₂), tantalum oxide (Ta₂O₅), zinc oxide (ZnOₓ), silicon oxide (SiO₂), silicon nitride (SiNₓ), and/or silicon oxynitride (SiON). The organic encapsulation layer may include a polymer-based material. The polymer-based material may include an acrylic resin, an epoxy-based resin, polyimide, polyethylene, and/or the like. In one or more embodiments, the organic encapsulation layer may include acrylate.

The disclosure has been described with reference to the embodiments shown in the drawings, but these are merely for the purposes of illustration, and those skilled in the art will understand that one or more suitable modifications and equivalent other embodiments are possible. Therefore, the scope of protection of the present disclosure should be determined by the spirit and scope of the appended claims and equivalents.

The light-emitting diode according to one or more embodiments includes a mixed layer arranged between an electron transport layer and an auxiliary electron transport layer to facilitate electron movement from an opposite electrode to an emission layer, thereby reducing the driving voltage of the light-emitting diode. In the deposition apparatus according to one or more embodiments, the angle of angle-limiting plates are set such that a mixed layer is formed between an electron transport layer and an auxiliary electron transport layer, thereby reducing (e.g., effectively reducing) the driving voltage of the light-emitting diode formed by the deposition apparatus. However, the scope of the present disclosure is not limited by the above-described effects.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in other embodiments. Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A light-emitting diode comprising:
a pixel electrode;
a first functional layer on the pixel electrode;
an emission layer on the first functional layer;
a second functional layer on the emission layer; and
an opposite electrode on the second functional layer,
wherein
the second functional layer comprises:
an auxiliary electron transport layer on the emission layer and comprising a first deposition material;
a mixed layer on the auxiliary electron transport layer and comprising the first deposition material, a second deposition material, and a third deposition material; and
an electron transport layer on the mixed layer and comprising the second deposition material and the third deposition material.

2. The light-emitting diode of claim 1, wherein a lowest unoccupied molecular orbit (LUMO) energy level of the mixed layer is lower than a LUMO energy level of the auxiliary electron transport layer and higher than a LUMO energy level of the electron transport layer.

3. The light-emitting diode of claim 2, wherein the LUMO energy level of the auxiliary electron transport layer is lower than the LUMO energy level of the emission layer.

4. The light-emitting diode of claim 2, wherein a highest occupied molecular orbit (HOMO) energy level of the mixed layer is lower than a HOMO energy level of the emission layer and a HOMO energy level of the electron transport layer.

5. The light-emitting diode of claim 1, wherein a thickness of the mixed layer is less than a thickness of the electron transport layer.

6. The light-emitting diode of claim 1, wherein a thickness of the mixed layer is about 20 angstrom (Å) to about 70 Å.

7. The light-emitting diode of claim 1, wherein a thickness of the mixed layer is equal to or greater than a thickness of the auxiliary electron transport layer.

8. A display device comprising:
a substrate;
a thin film transistor on the substrate;
a pixel electrode electrically connected to the thin film transistor;
a first functional layer on the pixel electrode;
an emission layer on the first functional layer;
a second functional layer on the emission layer; and
an opposite electrode on the second functional layer,
wherein
the second functional layer comprises:
an auxiliary electron transport layer on the emission layer and comprising a first deposition material;
a mixed layer on the auxiliary electron transport layer and comprising the first deposition material, a second deposition material, and a third deposition material; and
an electron transport layer on the mixed layer and comprising the second deposition material and the third deposition material.

9. The display device of claim 8, wherein a lowest unoccupied molecular orbit (LUMO) energy level of the mixed layer is lower than a LUMO energy level of the auxiliary electron transport layer and higher than a LUMO energy level of the electron transport layer.

10. The display device of claim 9, wherein the LUMO energy level of the auxiliary electron transport layer is lower than the LUMO energy level of the emission layer.

11. The display device of claim 9, wherein a highest occupied molecular orbit (HOMO) energy level of the mixed layer is lower than a HOMO energy level of the emission layer and a HOMO energy level of the electron transport layer.

12. The display device of claim 8, wherein a thickness of the mixed layer is less than a thickness of the electron transport layer.

13. The display device of claim 8, wherein a thickness of the mixed layer is about 20 angstrom (Å) to about 70 Å.

14. A deposition apparatus for forming a functional layer comprising an electron transport layer on a deposition substrate, the deposition apparatus comprising:
a first deposition source, a second deposition source, and a third deposition source arranged with each other in a first direction;
a first spray port configured to spray a first deposition material from the first deposition source to a first region of the deposition substrate;
a second spray port configured to spray a second deposition material from the second deposition source to a second region of the deposition substrate;
a third spray port configured to spray a third deposition material from the third deposition source to a third region of the deposition substrate;
a first angle-limiting plate located outside the first spray port;
a second angle-limiting plate between the first spray port and the second spray port;
a third angle-limiting plate between the second spray port and the third spray port; and
a fourth angle-limiting plate located outside the third spray port,
wherein a portion of the first region overlaps with the second region and the third region.

15. The deposition apparatus of claim 14, wherein the second region entirely overlaps the third region.

16. The deposition apparatus of claim 14, wherein the first spray port is limited by the first angle-limiting plate to spray the first deposition material at a first incident angle to the deposition substrate, the first spray port is limited by the second angle-limiting plate to spray the first deposition material at a second incident angle to the deposition substrate, and the first incident angle is greater than the second incident angle.

17. The deposition apparatus of claim 16, wherein the second spray port is limited by the second angle-limiting plate to spray the second deposition material at a third incident angle to the deposition substrate and the second incident angle is less than the third incident angle.

18. The deposition apparatus of claim 17, wherein the second incident angle is about 55° to about 65°.

19. The deposition apparatus of claim 18, wherein the third incident angle is about 70° to about 80°.

20. The deposition apparatus of claim 17, wherein
the second spray port is limited by the third angle-limiting plate to spray the second deposition material at a fourth incident angle to the deposition substrate,
the third spray port is limited by the third angle-limiting plate to spray the third deposition material at a fifth incident angle to the deposition substrate,
the fourth incident angle is smaller than the third incident angle,
the fourth incident angle is smaller than the fifth incident angle, and
the fifth incident angle is smaller than the third incident angle.
